(19) United States
(12) Patent Application Publication
(10) Pub. No.: US 2026/0136978 A1
(43) Pub. Date: May 14, 2026

(54) METHOD OF MANUFACTURING SEMICONDUCTOR DEVICE

(71) Applicant: SAMSUNG ELECTRONICS CO., LTD., Suwon-si (KR)

(72) Inventor: Kahyun SUN, Suwon-si (KR)

(73) Assignee: SAMSUNG ELECTRONICS CO., LTD., Suwon-si (KR)

(21) Appl. No.: 19/227,740

(22) Filed: Jun. 4, 2025

(30) Foreign Application Priority Data
Nov. 13, 2024 (KR) 10-2024-0160815

(51) Int. Cl. H01L 23/00

(52) U.S. Cl. CPC H10W 72/072; H10W 72/0711; H10W 72/07173; H10W 72/07178; H10W 72/07204

(57) ABSTRACT

A method of manufacturing a semiconductor device, includes providing an adhesive layer at a first temperate on a first surface of a first semiconductor chip, emitting an infrared ray onto the adhesive layer, and fixing the adhesive layer to the first surface of the first semiconductor chip, wherein the adhesive layer includes a first photothermal nanoparticles and a first polymer, and wherein a glass transition temperature of the adhesive layer is 35° C. to 65° C.

### CROSS-REFERENCE TO RELATED APPLICATIONS

This application claims priority under 35 U.S.C. § 119 to Korean Patent Application No. 10-2024-0160815 filed on Nov. 13, 2024, in the Korean Intellectual Property Office, the entire contents of which are hereby incorporated by reference herein.

### BACKGROUND

The present disclosure relates to a semiconductor package and a method of manufacturing the same, and more specifically, to a stacked semiconductor package in which a plurality of semiconductor chips are stacked on a substrate and a method of manufacturing the same.

High-performance, high-speed, and small electronic components have been increasingly demanded with the development of the electronics industry. To satisfy these demands, a packaging technique of providing a plurality of semiconductor chips in a single package has been suggested.

Recently, portable devices have been increasingly demanded in the electronics market, and thus small and light electronic components mounted in the electronics have been used. A semiconductor package technique of integrating a plurality of individual components in a single package as well as a technique of reducing a size of an individual component may be desirable to realize small and light electronic components.

### SUMMARY

One or more embodiments provide a semiconductor package which may have improved productivity.

One or more embodiments also provide a method of manufacturing a semiconductor package which may have a simplified process and a semiconductor package manufactured using the same.

The problem to be solved by the present disclosure is not limited to the problems mentioned above, and other problems not mentioned may be clearly understood by those skilled in the art from the description below.

According to an aspect of one or more embodiments, there is provided a method of manufacturing a semiconductor device, the method including providing an adhesive layer at a first temperature on a first surface of a first semiconductor, emitting an infrared ray onto the adhesive layer, and fixing the adhesive layer to the first surface of the first semiconductor chip, wherein the adhesive layer includes a first photothermal nanoparticles and a first polymer, and wherein a glass transition temperature of the adhesive layer is 35° C. to 65° C.

According to another aspect of one or more embodiments, there is provided a method of manufacturing a semiconductor device, the method including providing a first semiconductor chip, providing an adhesive layer at a first temperature on a first surface of the first semiconductor chip, emitting an infrared ray onto the adhesive layer, and fixing the adhesive layer on the first surface of the first semiconductor chip, wherein the adhesive layer includes first photothermal nanoparticles and a first polymer, wherein the emitting of the infrared ray includes heating the adhesive layer from the first temperature to a second temperature, wherein the first semiconductor chip includes a groove on the first surface, and wherein the emitting of the infrared ray includes filling the groove with the adhesive layer.

According to yet another aspect of one or more embodiments, there is provided a method of manufacturing a semiconductor device including providing a first semiconductor chip, providing an adhesive layer at a first temperature on a first surface of the first semiconductor chip, emitting an infrared ray to heat the adhesive layer from the first temperature to a second temperature, fixing the adhesive layer to the first surface of the first semiconductor chip, providing the first semiconductor chip on an interposer substrate, and separating the adhesive layer from the first semiconductor chip, wherein the adhesive layer includes first photothermal nanoparticles and a first polymer, wherein the first temperature is lower than a glass transition temperature of the adhesive layer, wherein the second temperature is higher than the glass transition temperature of the adhesive layer, and wherein a wavelength of the infrared ray is 750 nm to 850 nm.

### BRIEF DESCRIPTION OF THE DRAWINGS

Example embodiments will be more clearly understood from the following brief description taken in conjunction with the accompanying drawings, in which:

FIG. 1 is a flowchart illustrating a method of manufacturing a semiconductor package according to one or more embodiments;

FIGS. 2A, 3A, 4A, 5, 6A, and 7 are views for illustrating a method of manufacturing a semiconductor package according to one or more embodiments;

FIG. 2B is an enlarged view of portion ‘P1’ of FIG. 2A;

FIG. 3B is an enlarged view of portion ‘P1’ of FIG. 3A;

FIG. 4B is an enlarged view of portion ‘P1’ of FIG. 4A;

FIG. 6B is an enlarged view of portion ‘P1’ of FIG. 6A;

FIG. 8 is a plan view of a semiconductor package according to one or more embodiments;

FIG. 9 is a cross-sectional view taken along line I-I′ of FIG. 8; and

FIGS. 10, 11, 12, and 13 are drawings for illustrating a method of manufacturing a semiconductor package according to one or more embodiments.

### DETAILED DESCRIPTION

Hereinafter, embodiments will be described with reference to the attached drawings. Embodiments described herein are examples, and thus, the disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

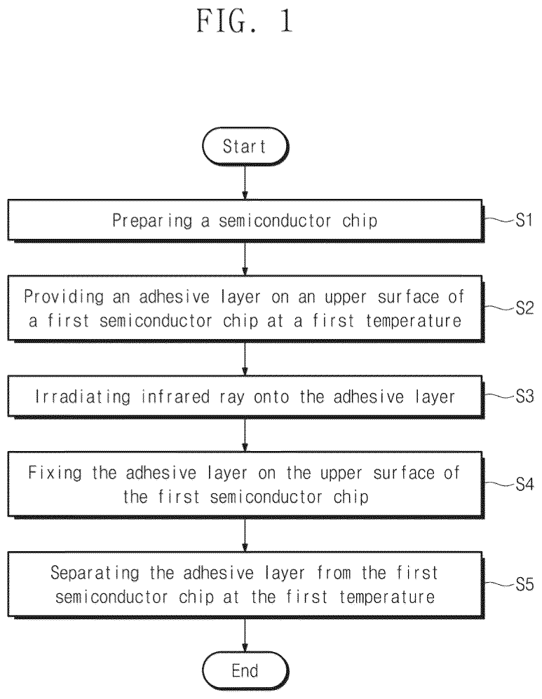

FIG. 1 is a flowchart illustrating a method of manufacturing a semiconductor package according to one or more embodiments.

Referring to FIG. 1, a method of manufacturing a semiconductor package according to one or more embodiments may include preparing a semiconductor chip in S1, providing an adhesive layer on an upper surface of the semiconductor chip at a first temperature in S2, emitting an infrared ray on the adhesive layer in S3, fixing the adhesive layer to the upper surface of the semiconductor chip in S4, and separating the adhesive layer from the semiconductor chip at the first temperature in S5.

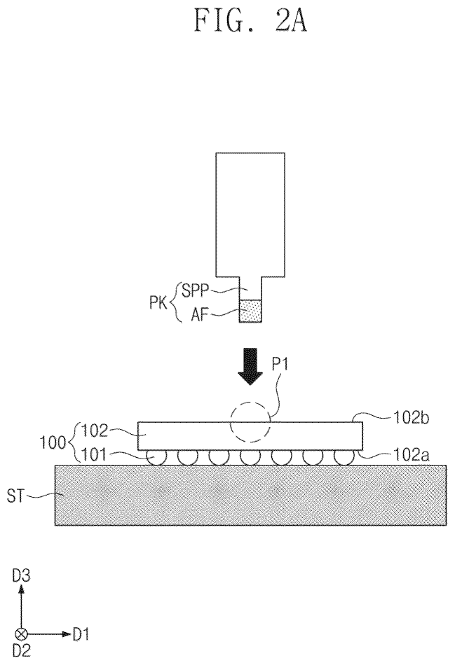

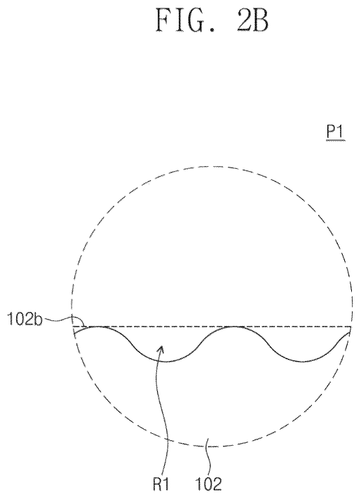

Hereinafter, each step will be described in detail with reference to FIGS. 2A to 7.

FIGS. 2A and 2B are views for illustrating the preparing of the semiconductor chip in S1. FIG. 2B is an enlarged view of region ‘P1’ of FIG. 2A.

Referring to FIGS. 2A and 2B, a chip 100 may be disposed on a stage ST. The stage ST may be a support for supporting the chip 100. The chip 100 may be manufactured on the stage ST. The chip 100 may include a circuit board portion 102 having an integrated circuit and connection terminals 101. As another example, the chip 100 may not include connection terminals 101. The connection terminals 101 may be, for example, any one of a solder ball, a bump, and a pillar. According to one or more embodiments, the chip 100 may include at least one of a logic die, a logic chip, a base die, a buffer chip, a buffer die, a memory controller, a dynamic random access memory (DRAM), a static random access memory (SRAM), a NAND-FLASH, and a high bandwidth memory (HBM), but is not limited thereto. The circuit board portion 102 may include a first surface 102a and a second surface 102b opposite to the first surface 102a.

The first surface 102a may be a surface of the chip 100 adjacent to a substrate 200 to be described later. The second surface 102b may be a surface of the chip 100 adjacent to a chip picker PK to be described later. The first surface 102a may be a lower surface of the circuit board portion 102. The second surface 102b may be an upper surface of the chip 100 and/or an upper surface of the circuit board portion 102. The connection terminals 101 may be provided on the first surface 102a. The second surface 102b of the chip 100 may include a curved surface. The second surface 102b of the chip 100 may include a micro-groove R1. The micro-groove R1 may be a nano-unit-sized curved region created during the processing of the second surface 102b. A roughness of the second surface 102b may be variously changed depending on the number or size of the micro-grooves R1.

A chip picker PK may be provided on the chip 100. The chip picker PK may include a support SSP and an adhesive layer AF. The support SSP may be a portion that includes all of the components of the chip picker PK except for the adhesive layer AF. The adhesive layer AF may be provided on a protruding portion of the chip picker PK. As another example, the chip picker PK may include a plurality of adhesive layers AF. A thickness and number of the adhesive layers AF are not limited to the drawings of this specification and may be arbitrarily adjusted by the user.

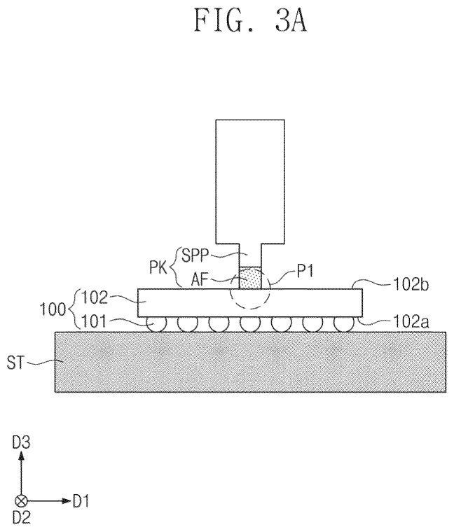

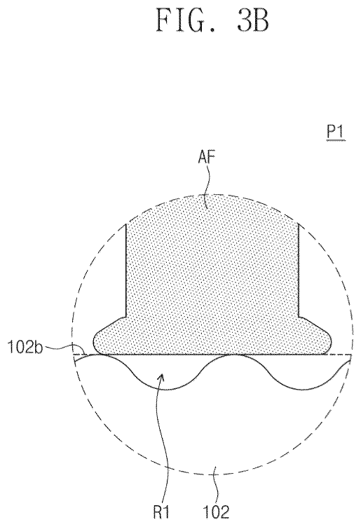

FIGS. 3A and 3B are views for illustrating the providing of the adhesive layer on the upper surface of the semiconductor chip at the first temperature in S2. FIG. 3B is an enlarged view of portion ‘P1’ of FIG. 3A.

Referring to FIGS. 3A and 3B, a chip picker PK may be provided on the second surface 102b of the chip 100 at a first temperature. An adhesive layer AF may be adjacent to the second surface 102b of the chip 100.

A glass transition temperature Tg of the adhesive layer AF may be 35° C. to 80° C. For example, the glass transition temperature Tg of the adhesive layer AF may be 35° C. to 65° C. At a temperature lower than the glass transition temperature Tg, the adhesive layer AF may be in a hard solid form. At a temperature higher than the glass transition temperature Tg, the adhesive layer AF may have viscoelasticity and be flexible similar to rubber. The first temperature may be a temperature lower than the glass transition temperature of the adhesive layer AF. The adhesive layer AF may be in a hard solid form at the first temperature. Accordingly, the adhesive layer AF may not be provided in the micro-grooves R1 of the second surface 102b.

The adhesive layer AF may include the first photothermal nanoparticles and the first polymer. As another example, the adhesive layer AF may include a plurality of different polymers. The first photothermal particles may be dispersed in a matrix structure of the first polymer. The first photothermal particles may be particles that absorb light and convert the light into heat. The first photothermal particles may selectively absorb light of a specific wavelength and release the absorbed energy as heat. As a result, the first photothermal particles may increase the surrounding temperature. For example, the first photothermal particles may include any one of gold, silver, carbon nanotubes, iron oxide, and copper.

The first polymer may include a first monomer and a first crosslinker. The first polymer may have a matrix structure. This is because the first monomer and the first crosslinker form the matrix structure through a polymerization reaction. For example, the first polymer may include any one of polyurethane (PU), polystyrene (PS), polyvinyl saccharate (PVA), polycarbonate (PC), ethylene-vinyl acetate (EVA), polymethacrylate (PMA), polyacrylate (PA), polybutyl acrylate (PBA), polyacrylonitrile (PAN), polymethyl methacrylate (PMMA), and polyacrylate (PAC).

For example, the first monomer may include at least one selected from the group consisting of isobornyl methacrylate, 2-phenylethyl acrylate, isodecyl methacrylate, acrylic acid, methacrylic acid, acrylonitrile, butyl acrylate, isooctyl acrylate, vinyl acetate, methyl methacrylate, and itaconic acid (IA). For example, the first crosslinker may include at least one of aliphatic urethane acrylate, hexamethylene diisocyanate trimer, isophorone diisocyanate, trimethylolpropane triacrylate, perylene dicarboxylate, hexamethylene diol diacrylate, dipentaerythritol hexaacrylate, triethylene glycol diacrylate, and urethane diacrylate.

In another example, the first polymer may further include a second monomer. The second monomer may have a different glass transition temperature from a glass transition temperature of the first monomer. A glass transition temperature of the first polymer may be controlled by adjusting a ratio of the first monomer to the second monomer. In another example, the first polymer may include a plurality of different monomers.

The first polymer may include an initiator. The initiator may generate free radicals to promote the polymerization reaction of the first monomer. For example, the initiator may be, but is not limited to, one of azobisisobutyronitrile (AIBN) and divinylbenzene (DVB).

The adhesive layer AF may further include a first inorganic filler. The first inorganic filler may increase the dispersibility of the first photothermal nanoparticles in the first polymer. In addition, structural stability and thermal stability of the adhesive layer AF may be improved by the adhesive layer AF including the first inorganic filler. For example, the first inorganic filler may include at least one of silica, calcium carbonate, alumina, and magnesium carbonate, for example.

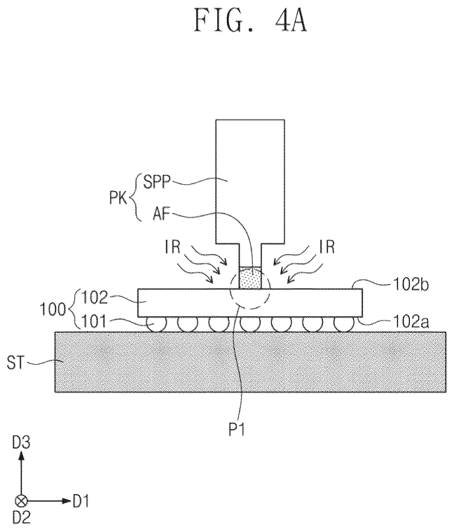

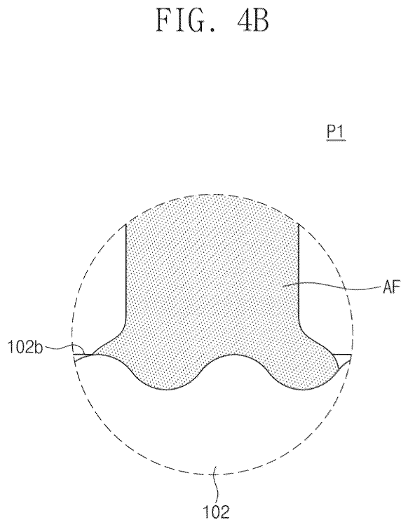

FIGS. 4A and 4B are views for illustrating the irradiating of the infrared ray onto the adhesive layer AF in S3. FIG. 4B is an enlarged view of portion ‘P1’ of FIG. 4A.

Referring to FIGS. 4A and 4B, infrared IR may be emitted to an region where the chip 100 and the adhesive layer AF are in contact. The infrared IR may be light emitted by high-energy ferromagnetic particles. A wavelength of the infrared IR may be 750 nm to 850 nm. For example, the wavelength of infrared IR may be 808 nm. As another example, the infrared IR may be selectively emitted to a portion of the adhesive layer AF. A user may adjust a region and an emission distance of infrared IR to emit infrared IR only to the intended region.

By emitting infrared IR, a photothermal effect by the first photothermal nanoparticle of the adhesive layer AF may be generated. For example, the first photothermal nanoparticle may absorb infrared IR and convert the absorbed energy into heat and emit the energy. Accordingly, the first photothermal nanoparticle may increase the temperature of the adhesive layer AF as increasing the surrounding temperature.

The emitting of the infrared IR may include increasing the temperature of the adhesive layer AF from a first temperature to a second temperature. The second temperature may be higher than the first temperature. The second temperature may be higher than the glass transition temperature of the adhesive layer AF. At the second temperature, the adhesive layer AF may have viscoelasticity and fluidity. At the second temperature, the adhesive layer AF may be in a flexible state similar to rubber. As the temperature increases, the viscoelasticity of the adhesive layer AF may increase. The adhesive layer AF at the second temperature may have lower stiffness than a stiffness of the adhesive layer AF at the first temperature.

At the second temperature, the adhesive layer AF may fill the micro-grooves R1 of the second surface 102b based on the adhesive layer AF having flexibility at the second temperature, and thus a shape of the adhesive layer AF may be physically deformed. The adhesive layer AF may be deformed to correspond to a slight curvature of the second surface 102b of the chip 100. The area of the adhesive layer AF in contact with the chip 100 may increase.

As the temperature of the adhesive layer AF increases, the adhesion between the adhesive layer AF and the chip 100 may increase. For example, as a contact area between the adhesive layer AF and the chip 100 increases, van der Waals force and/or hydrogen bonding force at an interface between the adhesive layer AF and the chip 100 may increase. For example, as the contact area of the adhesive layer AF and the chip 100 increases and the van der Waals or hydrogen bonding force between these interfaces increases, the adhesion between the adhesive layer AF and the chip 100 may be maximized.

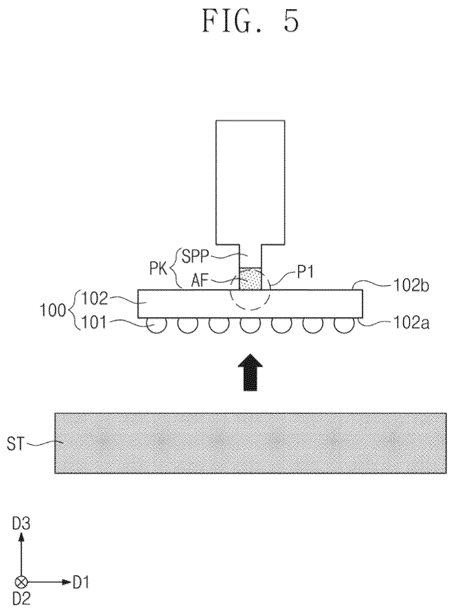

FIG. 5 is a view for illustrating the fixing of the adhesive layer AF to the upper surface of the chip 100 in S4.

Referring to FIG. 5, the adhesive layer AF and the chip 100 may be adhered along the micro-curves of the contact area thereof. Thereafter, the chip 100 may be separated from the stage ST. Due to the strong adhesion between the chip 100 and the adhesive layer AF, the chip 100 may be stably separated from the stage ST. The chip 100 may be stably moved for another process while being fixed to the adhesive layer AF.

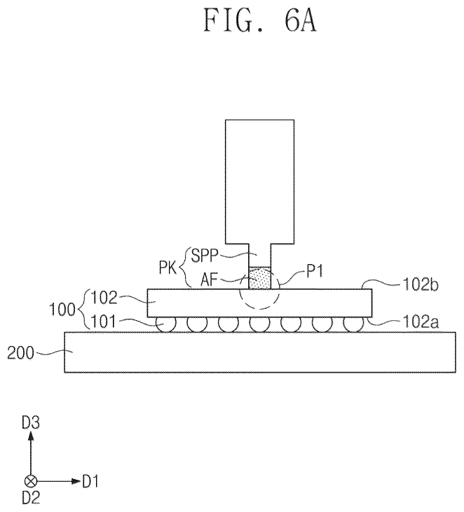

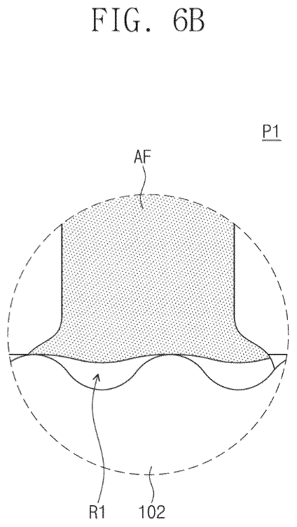

FIGS. 6A and 6B are views for illustrating the separating of the adhesive layer AF from the chip 100 at the first temperature in S5. FIG. 6B is an enlarged view of portion ‘P1’ of FIG. 6A.

Referring to FIGS. 6A and 6B, the chip 100 may be mounted on a substrate 200. The connection terminal 101 of the chip 100 may be connected to wirings of the substrate 200. As another example, the connection terminal 101 may be omitted, so that the first surface 102a of the chip 100 may be in direct contact with the substrate 200. Thereafter, the temperature of the adhesive layer AF may be lowered from the second temperature to the first temperature again. As a result, the adhesion between the adhesive layer AF and the chip 100 may be reduced. The adhesive layer AF may not fill the micro-groove R1 again. The area where the adhesive layer AF and the chip 100 come into contact may be reduced.

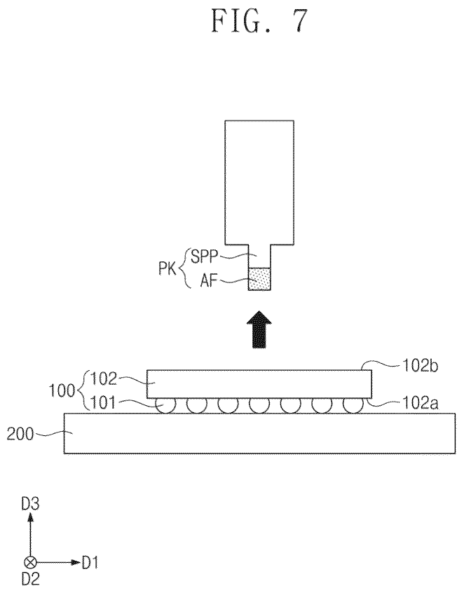

Referring to FIG. 7, the chip picker PK may be completely removed from the chip 100. Due to the relatively weak adhesion between the adhesive layer AF and the chip 100, the adhesive layer AF may be completely separated from the chip 100 without residue. As a result, a cleaning process after removing the adhesive layer AF may be unnecessary. As a result, the cleaning process may be omitted, thereby reducing costs and simplifying the process.

According to one or more embodiments, the chip 100 may be more easily mounted on the substrate 200 using the adhesive layer AF including the first photothermal nanoparticle and the first polymer. By emitting infrared IR onto the adhesive layer AF, the temperature of the adhesive layer AF may be increased above the glass transition temperature of the adhesive layer AF. As a result, the adhesive layer AF may be physically deformed to fill the micro-grooves on the surface of the chip 100. As the temperature increases, the adhesion between the adhesive layer AF and the chip 100 may be strengthened. By emitting infrared IR, the temperature may be quickly controlled, and heat damage to the adhesive layer AF may be minimized. In addition, the user may selectively emit infrared IR only the desired region by adjusting the emission distance of the infrared IR.

The temperature may be lowered again to reduce the adhesion between the adhesive layer AF and the chip 100. As a result, when the adhesive layer AF and the chip 100 are separated, the residue of the adhesive layer AF may not remain on the chip 100. According to one or more embodiments, the adhesion between the adhesive layer AF and the chip 100 may be more easily controlled by changing the temperature. Therefore, the adhesive layer AF may be used regardless of the state of the substrate 200, such as wettability of the substrate 200, a degree of O2 exposure, and roughness. The used adhesive layer AF may be reused. As a result, cost of the process may be reduced.

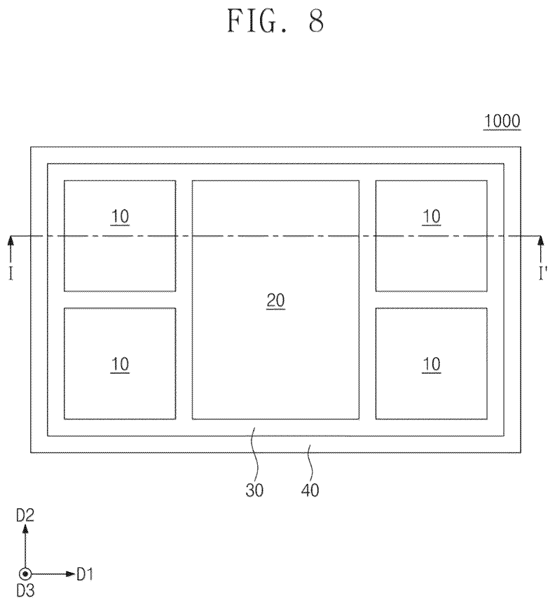

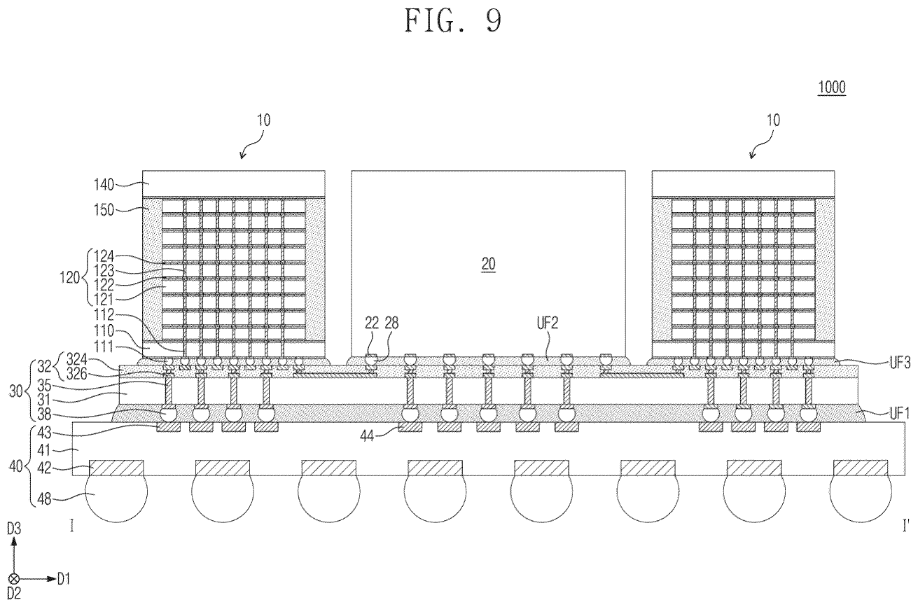

FIG. 8 is a plan view of a semiconductor package according to one or more embodiments. FIG. 9 is a cross-sectional view taken along line I-I′ of FIG. 8.

A semiconductor package will be described in detail with reference to FIGS. 8 and 9. The semiconductor package 1000 may further include a package substrate 40, an interposer 30, a third semiconductor chip 20, a plurality of chip stack structures 10, and underfill patterns UF1, UF2, and UF3.

The package substrate 40 may be, for example, a printed circuit board (PCB). The package substrate 40 may include a preliminary substrate 41, lower metal pads 42, first upper metal pads 43, second upper metal pads 44, metal wirings, and external connection terminals 48. The first upper metal pads 43 and the second upper metal pads 44 may be disposed on an upper portion of the package substrate 40, and the lower metal pads 42 may be disposed on a lower portion of the package substrate 40. The first upper metal pads 43 may overlap a chip stack structure 10 in a third direction D3. The second upper metal pads 44 may overlap the third semiconductor chip 20 in the third direction D3. The first upper metal pads 43 and the second upper metal pads 44 may each be in contact with first connection terminals 38 to be described later. The metal wirings may connect the first upper metal pads 43 and the second upper metal pads 44 to the lower metal pads 42. The external connection terminals 48 may be disposed on the lower metal pads 42, respectively. The external connection terminals 48 may include a conductive material such as, for example, solder.

The interposer 30 may be disposed on the package substrate 40. The interposer 30 may include an interposer substrate 31, fourth penetration electrodes 35, a wiring layer 32, and first connection terminals 38. The interposer substrate 31 may include a semiconductor such as silicon or germanium, and may be, for example, a silicon substrate. The wiring layer 32 may be disposed on the interposer substrate 31. The wiring layer 32 may include an interposer substrate 31 and a wiring structure 326 in the interposer substrate 31. The interposer substrate 31 may be an insulating layer such as a silicon oxide layer. The interposer substrate 31 is illustrated as being a single layer, but may include a plurality of insulating layers. The wiring structure 326 may electrically connect the third semiconductor chip 20 and the chip stack structure 10. Each of the fourth penetration electrodes 35 may penetrate the interposer substrate 31 and may be connected to the first connection terminal 38 through a pad or the like.

The first underfill pattern UF1 may be interposed between the interposer 30 and the package substrate 40. The first underfill pattern UF1 may include, for example, an epoxy resin composition. The first underfill pattern UF1 may fill a space between the first connection terminals 38.

The third semiconductor chip 20 and a plurality of chip stack structures 10 may be disposed on the interposer 30. For example, the third semiconductor chip 20 may be disposed at a center of the interposer 30. The chip stack structures 10 may be spaced apart from each other in a first direction D1 with the third semiconductor chip 20 interposed between the chip stack structures 10. As shown in FIG. 8, two chip stack structures 10 may be disposed adjacent to one side of the chip of the third semiconductor chip 20, and two chip stack structures 10 may be disposed adjacent to the other side of the chip of the third semiconductor chip 20. The adjacent chip stack structures 10 may be spaced apart from each other in a second direction D2.

According to some embodiments, three chip stack structures 10 may be disposed adjacent to one side of the third semiconductor chip 20, and three chip stack structures 10 may be disposed adjacent to the other side of the third semiconductor chip 20. A plurality of chip stack structures 10 may be provided, and the arrangement forms may be variously changed.

The chip stack structures 10 may be, for example, a high bandwidth memory (HBM). The chip stack structures 10 may include a first semiconductor chip 110, second semiconductor chips 120 on the first semiconductor chip 110, a dummy plate 140, and a molding structure 150.

In the present disclosure, the first semiconductor chip 110 may also be referred to as a logic die, a logic chip, a base die, a buffer chip, a buffer die, a memory controller, etc. The first semiconductor chip 110 may serve as a logic chip that increases efficiency of data transmission and reduces power consumption.

A connection terminal 111 may be disposed on a lower surface of the first semiconductor chip 110. The connection terminal 111 may be, for example, one of a solder ball, a bump, and a pillar. The connection terminal 111 may be connected to an under bump pattern disposed at an lower portion of the first semiconductor chip 110.

A first penetration electrode 112 may penetrate the first semiconductor chip 110. The first penetration electrode 112 may include a conductive material such as, for example, copper. A diffusion barrier pattern such as, for example, tantalum nitride (TaN), tantalum (Ta), titanium nitride (TiN), and tungsten (W) may be disposed between the first penetration electrode 112 and the first semiconductor chip 110.

The second semiconductor chips 120 may be stacked on the first semiconductor chip 110. Each of the second semiconductor chips 120 may be a memory chip. The second semiconductor chip 120 may be, for example, any one of DRAM, SRAM, and NAND-FLASH. The second semiconductor chip 120 may be a semiconductor chip of the same type having the same integrated circuit.

The second semiconductor chip 120 may include a stacked semiconductor substrate 121, a lower wiring layer 122, a second penetration electrode 123, and an upper wiring layer 124.

The stacked semiconductor substrate 121 may include a semiconductor material such as silicon (Si). The stacked semiconductor substrate 121 may have a thickness substantially the same in the third direction D3 in the first direction D1 and/or the second direction D2.

The lower wiring layer 122 may be disposed below the second semiconductor chip 120. The lower wiring layer 122 may include a lower insulating layer, a lower wiring pattern, and a lower bonding pad. The lower insulating layer may include at least one of, for example, silicon oxide (SiO₂), silicon nitride (Si₃N₄), and silicon oxynitride (SiOxNy). The lower insulating layer may be composed of a plurality of insulating layers. The lower wiring layer may include a plurality of wiring lines and vias connected thereto. One side of the lower bonding pad may be connected to the lower wiring pattern, and the other side thereof may be in contact with an upper bonding pad of another second semiconductor chip 120 to be described later.

An upper wiring layer 124 may be disposed on an upper portion of the second semiconductor chip 120. The upper wiring layer 124 may include an upper insulating layer and an upper bonding pad. The upper insulating layer may include, for example, at least one of silicon oxide (SiO₂), silicon nitride (Si₃N₄), and silicon oxynitride (SiOxNy). The upper insulating layer may be composed of a plurality of insulating layers. The upper bonding pad may be interposed in the upper insulating layer. The upper bonding pad of the second semiconductor chip 120 may be directly connected to the lower bonding pad of another second semiconductor chip 120 adjacent thereto.

The second penetration electrode 123 may penetrate the stacked semiconductor substrate 121. The second penetration electrode 123 may include, for example, a conductive material such as copper. Between the second penetration electrode 123 and the stacked semiconductor substrate 121, a diffusion barrier pattern such as, for example, tantalum nitride (TaN), tantalum (Ta), titanium nitride (TiN), and tungsten (W) may be disposed. A first end of the second penetration electrode 123 may be connected to the lower bonding pad, and a second end may be connected to the lower wiring pattern.

The molding structure 150 may be provided on and cover an upper surface of the first semiconductor chip 110 and a side surface of the second semiconductor chips 120. The molding structure 150 may include an insulating material such as, for example, an epoxy molding compound (EMC). The molding structure 150 may be disposed between the upper surface of the first semiconductor chip 110 and a lower surface of the dummy plate 140.

The dummy plate 140 may be disposed on the uppermost second semiconductor chip 120 among the second semiconductor chips 120. The dummy plate 140 may include a semiconductor material such as silicon or germanium. For example, the dummy plate 140 may be a silicon substrate. The dummy plate 140 may not include components such as integrated circuits, wiring patterns, and penetration electrodes. The third semiconductor chip 20 may be a logic chip.

The third semiconductor chip 20 may be, for example, any one of a central processing unit (CPU), a graphics processing unit (GPU), and an application specific integrated circuit (ASIC). The third semiconductor chip 20 may transmit a signal to the chip stack structure 10 or receive a signal from the chip stack structure 10. The third semiconductor chip 20 may include chip pads 22 thereunder. Second connection terminals 28 may be respectively disposed on the chip pads 22. The second connection terminals 28 may include a conductive material such as solder.

The second connection terminal 28 of the third semiconductor chip 20 and a connection terminal 180 of the chip stack structure 10 may be in contact with the pads on the upper surface of the interposer 30. A second underfill pattern UF2 may be disposed between the third semiconductor chip 20 and the interposer 30. The second underfill pattern UF2 may fill a space between the second connection terminals 28. A third underfill pattern UF3 may be interposed between the chip stack structure 10 and the interposer 30. The third underfill pattern UF3 may fill a space between the connection terminals 180. The second underfill pattern UF2 and the third underfill pattern UF3 may include, for example, an epoxy resin composition.

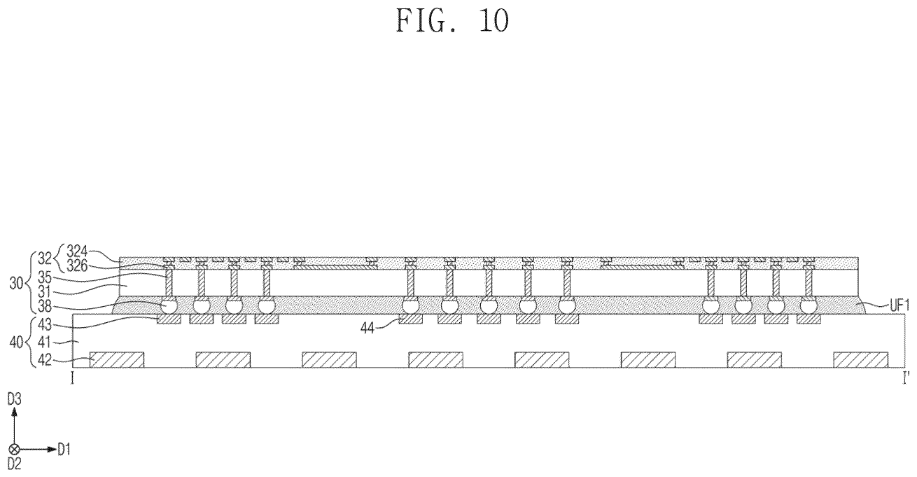

FIGS. 10, 11, 12, and 13 are views for illustrating a method of manufacturing a semiconductor package according to one or more embodiments. Referring to FIG. 10 to FIG. 13, a method of manufacturing a semiconductor package according to one or more embodiments will be described in more detail. Technical features overlapping those described with reference to FIG. 2A to FIG. 7 will be omitted.

Referring to FIG. 10, a package substrate 40 may be formed. Forming the package substrate 40 may include forming lower metal pads 42, first upper metal pads 43, and second upper metal pads 44 in a preliminary substrate 41.

An interposer 30 may be mounted on the package substrate 40. The interposer 30 may be disposed on the package substrate 40 in a completed state. The first connection terminals 38 of the interposer 30 may be disposed on the first and second upper metal pads 43 and 44 of the package substrate 40. The first underfill pattern UF1 may be provided between the interposer 30 and the package substrate 40. The first underfill pattern UF1 may fill a space between the first connection terminals 38 of the interposer 30.

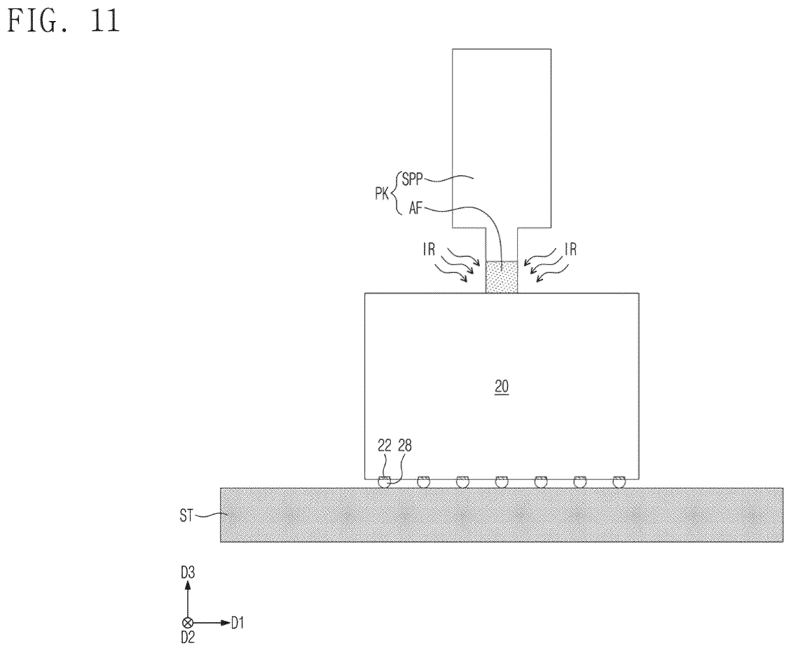

Referring to FIG. 11, a completed third semiconductor chip 20 may be provided on a stage ST. The third semiconductor chip 20 may be manufactured on the stage ST. A chip picker PK may be provided on an upper surface of the third semiconductor chip 20 at a first temperature. An adhesive layer AF of the chip picker PK may be in contact with an upper surface of the third semiconductor chip 20.

Afterwards, infrared IR may be emitted on the adhesive layer AF adjacent to the logic chip 20. By emitting the infrared IR, a photothermal effect due to the first photothermal nanoparticles in the adhesive layer AF may be generated. As a result, the temperature of the adhesive layer AF may increase to a second temperature higher than a glass transition temperature Tg of the adhesive layer AF. As a result, adhesion between the adhesive layer AF and an upper surface of the third semiconductor chip 20 may increase.

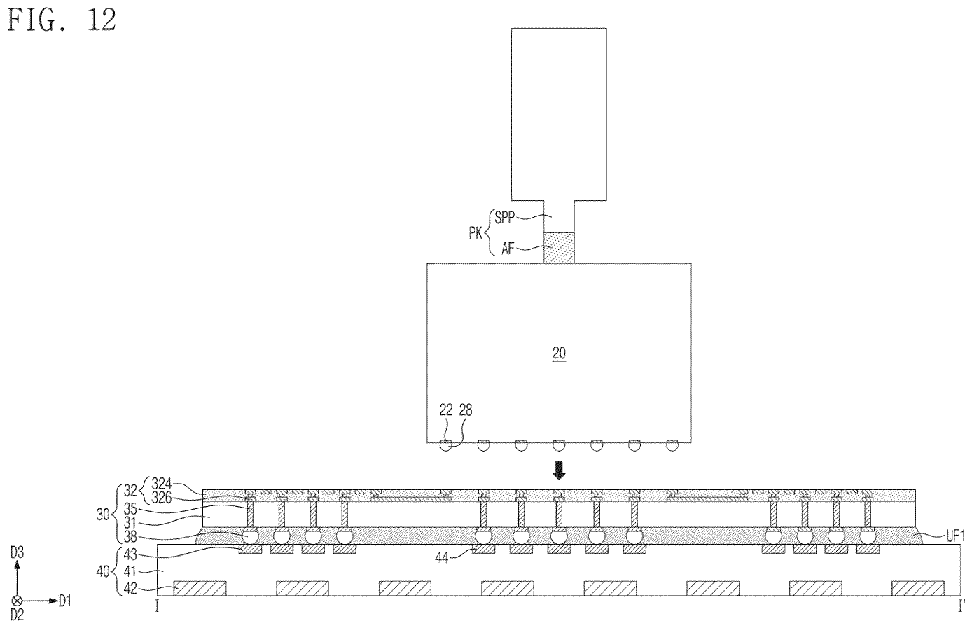

Referring to FIG. 12, the adhesive layer AF and the fixed third semiconductor chip 20 may be separated from the stage ST. The third semiconductor chip 20 may be stably separated and moved by the adhesive layer AF. The separated third semiconductor chip 20 may be provided on the interposer 30. The second connection terminals 28 of the third semiconductor chip 20 may be disposed on the conductive pads in the interposer substrate 31 of the interposer 30.

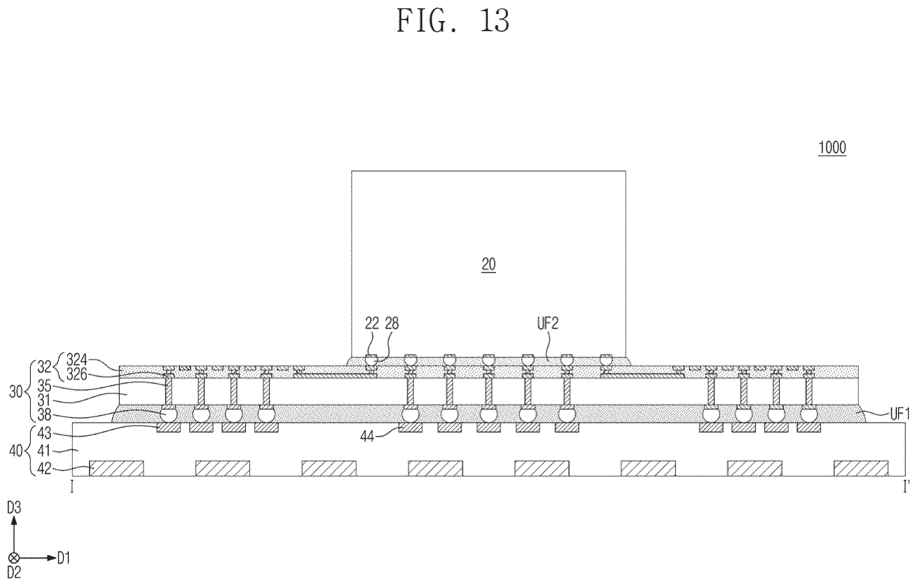

Referring to FIG. 13, after the third semiconductor chip 20 is mounted on the interposer 30, the chip picker PK may be separated from the third semiconductor chip 20. To separate the adhesive layer AF of the chip picker PK from the third semiconductor chip 20, the temperature of the adhesive layer AF that has been heated by infrared IR may be lowered back to the first temperature. As a result, the adhesion between the adhesive layer AF and the third semiconductor chip 20 may be reduced. As the adhesion is reduced, the adhesive layer AF may be completely separated from the third semiconductor chip 20 without any residue. Accordingly, an additional cleaning process on the third semiconductor chip 20 may be omitted.

A second underfill pattern UF2 may be provided between the third semiconductor chip 20 and the interposer 30. The second underfill pattern UF2 may fill a space between the second connection terminals 28.

Referring again to FIGS. 8 and 9, chip stack structures 10 may be mounted on both sides of the third semiconductor chip 20. Mounting the chip stack structures 10 on the interposer 30 may be substantially the same as described with reference to FIGS. 11 and 13. Thereafter, external connection terminals 48 may be respectively disposed on the lower metal pads 42 of the package substrate 40. The external connection terminals 580 may include a conductive material such as solder.

As another example, mounting the interposer 30 on the package substrate 40 may be substantially the same as described with reference to FIGS. 11 and 13. In addition, the method described with reference to FIGS. 11 and 13 may be applied to stacking not only the third semiconductor chip 20 and the interposer 30, but also the first and second semiconductor chips 110 and 120 in the chip stack structures 10. One or more embodiments may also be applied to mounting a die on a substrate, a semiconductor chip on a substrate, another semiconductor chip on a semiconductor chip, and a die on a die.

According to one or more embodiments, the chip may be more easily mounted on the substrate using the adhesive layer including the photothermal nanoparticles and the polymer. By emitting an infrared ray on the adhesive layer, the temperature of the adhesive layer may be raised higher than the glass transition temperature of the adhesive layer. As a result, the adhesive layer may be physically deformed to fill the micro-grooves on the surface of the chip. As the temperature rises, the adhesion between the adhesive layer and the chip may be strengthened. By lowering the temperature again, the adhesion between the adhesive layer and the chip may be reduced. As a result, when the adhesive layer and the chip are separated, the residue of the adhesive layer may not remain on the chip.

While embodiments have been described with reference to the figures, it will be understood by those of ordinary skill in the art that various changes in form and details may be made therein without departing from the spirit and scope as defined by the following claims and their equivalents.

What is claimed is:

1. A method of manufacturing a semiconductor device, the method comprising:
providing an adhesive layer at a first temperature on a first surface of a first semiconductor chip;
emitting an infrared ray onto the adhesive layer; and
fixing the adhesive layer to the first surface of the first semiconductor chip,
wherein the adhesive layer comprises a first photothermal nanoparticles and a first polymer, and
wherein a glass transition temperature of the adhesive layer is 35°C to 65°C.

2. The method of claim 1, wherein the emitting of the infrared ray comprises heating the adhesive layer from the first temperature to a second temperature, and
wherein the second temperature is higher than the glass transition temperature of the adhesive layer.

3. The method of claim 2, wherein a stiffness of the adhesive layer at the second temperature is lower than a stiffness of the adhesive layer at the first temperature.

4. The method of claim 1, wherein the first photothermal nanoparticles comprise one of gold, silver, carbon nanotubes, iron oxide, and copper.

5. The method of claim 1, wherein the first polymer comprises a first monomer and a first crosslinker, and
wherein the first monomer comprises at least one of isobornyl methacrylate, 2-phenylethyl acrylate, isodecyl methacrylate, acrylic acid, methacrylic acid, acrylonitrile, butyl acrylate, isooctyl acrylate, vinyl acetate, methyl methacrylate, and itaconic acid.

6. The method of claim 5, wherein the first polymer further comprises a second monomer, and
wherein a glass transition temperature of the first monomer is different from a glass transition temperature of the second monomer.

7. The method of claim 1, wherein the adhesive layer further comprises a first inorganic filler, and
wherein the first inorganic filler comprises at least one of silica, calcium carbonate, alumina, and magnesium carbonate.

8. The method of claim 1, wherein the first polymer has a matrix structure, and
wherein the first photothermal nanoparticles are dispersed in the matrix structure of the first polymer.

9. The method of claim 1, wherein a wavelength of the infrared ray is 750 nm to 850 nm.

10. The method of claim 1, wherein the first surface of the first semiconductor chip comprises a groove, and
wherein the emitting of the infrared ray comprises filling the groove with the adhesive layer.

11. The method of claim 1, wherein the emitting of the infrared ray comprises increasing viscoelasticity of the adhesive layer.

12. The method of claim 1, further comprising separating the adhesive layer at the first temperature from the first semiconductor chip,
wherein the first temperature is lower than the glass transition temperature of the adhesive layer.

13. A method of manufacturing a semiconductor device, the method comprising:
providing a first semiconductor chip;
providing an adhesive layer at a first temperature on a first surface of the first semiconductor chip;
emitting an infrared ray onto the adhesive layer; and
fixing the adhesive layer on the first surface of the first semiconductor chip,
wherein the adhesive layer comprises first photothermal nanoparticles and a first polymer,
wherein the emitting of the infrared ray comprises heating the adhesive layer from the first temperature to a second temperature,
wherein the first semiconductor chip comprises a groove on the first surface, and
wherein the emitting of the infrared ray comprises filling the groove with the adhesive layer.

14. The method of claim 13, wherein the second temperature is higher than a glass transition temperature of the adhesive layer.

15. The method of claim 13, wherein the first polymer comprises a first monomer, a second monomer, and a first crosslinker, and
wherein a glass transition temperature of the first monomer is different from a glass transition temperature of the second monomer.

16. The method of claim 13, wherein the first polymer has a matrix structure, and
wherein the first photothermal nanoparticles are dispersed in the matrix structure of the first polymer.

17. The method of claim 13, wherein a stiffness of the adhesive layer at the second temperature is lower than a stiffness of the adhesive layer at the first temperature.

18. The method of claim 13, wherein the emitting of the infrared ray comprises increasing viscoelasticity of the adhesive layer.

19. The method of claim 13, further comprising separating the adhesive layer from the first semiconductor chip at the first temperature,
wherein the first temperature is lower than a glass transition temperature of the adhesive layer.

20. A method of manufacturing a semiconductor device comprising:
providing a first semiconductor chip;
providing an adhesive layer at a first temperature on a first surface of the first semiconductor chip;
emitting an infrared ray to heat the adhesive layer from the first temperature to a second temperature;
fixing the adhesive layer to the first surface of the first semiconductor chip;
providing the first semiconductor chip on an interposer substrate; and
separating the adhesive layer from the first semiconductor chip,
wherein the adhesive layer comprises first photothermal nanoparticles and a first polymer,
wherein the first temperature is lower than a glass transition temperature of the adhesive layer,
wherein the second temperature is higher than the glass transition temperature of the adhesive layer, and
wherein a wavelength of the infrared ray is 750 nm to 850 nm.
